(19) United States
(12) Patent Application Publication
(10) Pub. No.: US 2008/0050847 A1
(43) Pub. Date: Feb. 28, 2008

(54) SINGLE IC-CHIP DESIGN ON WAFER WITH AN EMBEDDED SENSOR UTILIZING RF CAPABILITIES TO ENABLE REAL-TIME DATA TRANSMISSION

(75) Inventors: Oleg Gluschenkov, Poughkeepsie, NY (US); Timothy E. Little, Poughkeepsie, NY (US); Gary L. Snyder, Mechanicsburg, PA (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/923,856

(22) Filed: Oct. 25, 2007

Related U.S. Application Data
(62) Division of application No. 10/907,798, filed on Apr. 15, 2005.

(51) Int. Cl. H01L 21/00; G08B 1/08

(52) U.S. Cl. 438/6; 340/539.1; 340/539.22; 340/657; 438/14

(57) ABSTRACT

An apparatus and method for real-time monitoring process conditions of a semiconductor wafer processing operation. A semiconductor wafer subject to processing in a wafer processing tool is embedded with one or more sensor devices. In response to receipt of wireless electromagnetic signals, the embedded sensor devices are activated for generating sensory data. The electromagnetic signals are further utilized to activate a transmitter device provided in the wafer to wirelessly transmit the sensory data generated from the activated embedded sensor device. The transmitted electromagnetic signals comprising the sensory data are communicated to a control device for controlling processing conditions of the process tool based upon the received sensory data.

### RELATED APPLICATIONS

This application is a divisional of U.S. application Ser. No. 10/907,798, filed Apr. 15, 2005.

### BACKGROUND OF THE INVENTION

1. Field of the Invention

The present invention relates generally to semiconductor wafer fabrication and particularly, to an improved system and method for manufacturing semiconductor chips using real-time process condition data feedback.

2. Description of the Prior Art

In current semiconductor wafer fabrication processes and systems, there is no ‘real-time’ data feedback from monitor or product wafers that accurately reflects the process conditions to the wafer within a process tool during operation. Current methods used in monitoring process chamber parameters (e.g., temp, chuck e/s bias/heat zones, pressure, gas flows, plasmas) of most tools are in situ sensors remotely placed within the chamber. These do not provide real-time data feedback from monitor or product wafers that accurately reflect the process conditions as seen by the Si wafer within a process tool during operation or that can directly control the process tool. Available devices such as temp probes require timely setups and probe accuracy is questionable. Thermocouple wafers require wires leading from a wafer that are cumbersome and must have built-in feed-throughs to make connections to external recording devices. Thermocouples are bonded to the wafer surface, and use of temperature dots typically attached to the wafer surface display a color variant requiring visual distinction yielding lower accuracy and not applicable to product or to feedback information for tool adjustment. These methods are intrusive, time consuming, and not representative of actual wafer conditions, and are typically one time use applications.

It would be highly desirable to provide a system and a method to wirelessly communicate with the wafer while positioned in the process tool.

It would be further highly desirable to provide an active feedback path for real-time process tool adjustments based on conditions directly affecting the semiconductor wafer located within a given single chamber of a semiconductor process tool.

It would be additionally highly desirable to provide a system and method to communicate built-in sensor information from a monitor or product wafer to the process system for a precisely controlled ETCH or DEP process and apply real-time adjustments to critical parameters if and when necessary during the wafer processing sequence.

### SUMMARY OF THE INVENTION

It is an object of the present invention to provide an apparatus and method for monitoring semiconductor chamber processing parameters, such as temperature, using a monitor wafer with built-in sensor chips that communicate wafer sensor data via RF wireless communication to an external receiver.

It is a further object of the present invention to provide an apparatus and method that provides feedback data relating to process conditions, e.g., temperature, to processing tool controllers to use for real-time control of the chamber's critical temperature environment especially at the wafer surface. By having a fully populated monitor wafer with built-in temperature sensors able to communicate real-time, there is provided concurrent tool recipe development that greatly improves both chamber and chuck temperature accuracy.

It is yet a further object of the present invention to provide a system and method for fabricating a wafer that senses and communicates, via a wireless communications transmission, actual chamber operating conditions as seen by a typical process wafer. Parameters such as temperature, RF power, gas flows, pressures, DC bias voltages are observed and recorded for chamber to chamber matching. Such a monitor wafer could easily be moved from chamber to chamber and/or tool to tool to serve as a common calibration standard device.

Beneficial aspects of the present invention thus include, but are not limited to: 1) superior sensor profiling due to wireless transmission and true to life wafer positioning; 2) Improved tool utilization as a decreased amount of time is required to profile; 3) Improved process yield due to precise chamber matching; 4) Positional parametric data on the wafer allows tool to tool and within a tool (chamber to chamber) process parameter consistency; 5) Provides design of experiment data based on chip position on the wafer within the chamber; and, 6) Allows for real-time recipe development.

Thus, according to the invention, there is provided an apparatus and method for real-time monitoring process conditions of a semiconductor wafer processing operation. Particularly, the semiconductor wafer subject to processing in a wafer processing tool is embedded with one or more sensor devices. In response to receipt of wireless electromagnetic signals, the embedded sensor devices are activated for generating sensory data. The electromagnetic signals are further utilized to activate a transmitter device embedded in the wafer and associated with a particular sensor to wirelessly transmit the sensory data generated from the activated embedded sensor device. The wirelessly transmitted electromagnetic signals comprising the sensory data are communicated to a control device for controlling processing conditions of the process tool based upon the received sensory data.

### BRIEF DESCRIPTION OF THE DRAWINGS

The objects, features and advantages of the present invention will become apparent to one skilled in the art, in view of the following detailed description taken in combination with the attached drawings, in which:

FIG. 1 is a conceptual block diagram depicting a single semiconductor (e.g., silicon) monitor wafer 10 packaged with an array of embedded IC chips designed with wireless communications capabilities; and,

FIG. 2 illustrates a schematic diagram of a single detailed circuit block diagram depicting a single IC chip design embedded on the semiconductor wafer according to a preferred embodiment of the invention.

### DETAILED DESCRIPTION OF THE PREFERRED EMBODIMENTS

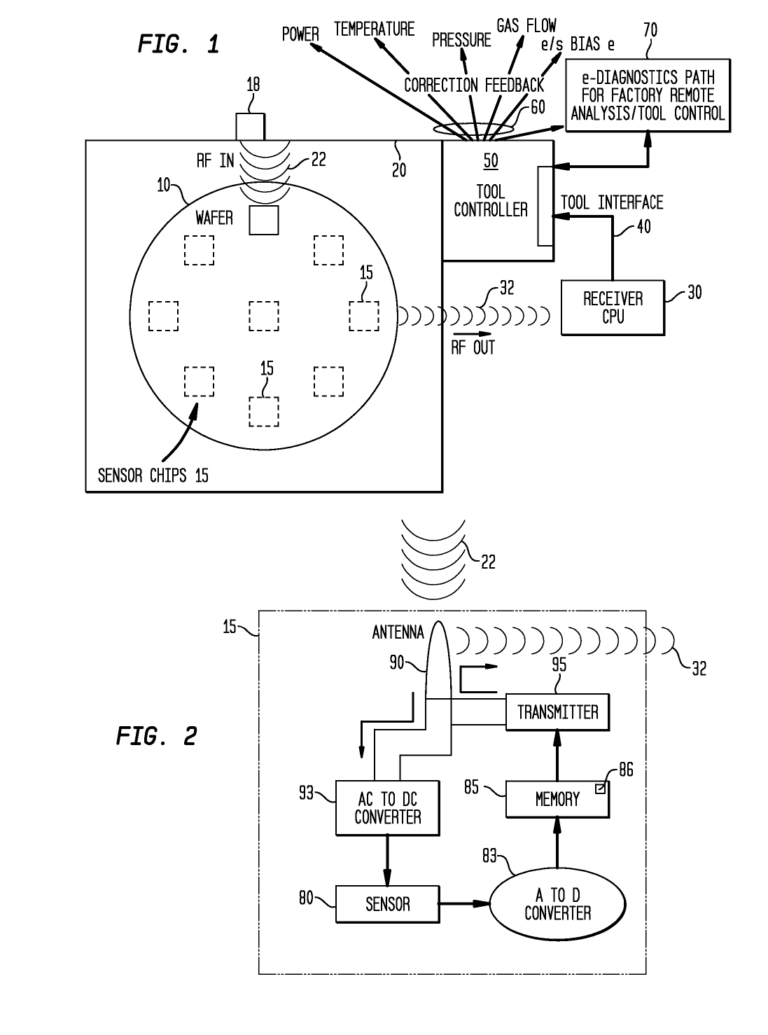

With reference to the accompanying drawings, FIG. 1 illustrates a schematic diagram of a single semiconductor (e.g., silicon) monitor wafer 10 packaged with an array of embedded IC chips designed with wireless communications capabilities. The monitor wafer is populated with a plurality of individual sensor device circuit chips 15 that utilize RF wireless transmission to communicate with an external RF communications receiver 30. As will be described, each chip has a unique identification (chip ID) associated therewith such that RF signals and process condition data received from a particular sensor device will be automatically identified and associated with that sensor. It is understood that while the exemplary embodiment described herein is directed to sensing of temperature by providing temperature sensor devices 15, it is understood that the apparatus is equally adapted to sense other process conditions such as, e.g., power, pressure, gas flow, e/s bias, etc. via suitable sensor devices 15.

In a semiconductor wafer processing tool, the monitor wafer 10 is indexed within a chamber 20 during tool operation. In response to an RF stimulus 22 provided by an RF source 18, the sensor chip 15 wirelessly transmits as an RF signal 32 the process condition data, e.g., chamber environmental parameter data such as actual temperature, sensed by each sensor chip 15 to an external receiver device 30. The receiver 30 receives and decodes the actual process condition data, e.g., actual temperature, sensed by each respective chip 15 and separately stores the temperature data by its chip ID based on its location on the wafer. The receiver includes built in intelligence, e.g., a microprocessor or like control process unit (CPU) for comparing the decoded temperature data against a set of predetermined tool temperature set-points and determines a correction delta (or new setpoints) that is passed to the process tool controller 50, via a tool interface 40, for either active or passive tool temperature control action 60. That is the tool interface responds with appropriate parameter adjustment and/or allows manual recipe intervention to adjust parameters. ‘Real-time’ automatic or manual temperature control adjustments for parameter calibration may then be applied as required. Recipe modifications or tool adjustments/calibrations can be applied directly and automatically by the tool controller 50 or, in a manual mode by process engineering. The wafer temperature data, or any other wafer sensory data obtained by the sensors, is also stored/filed in a memory storage device provided or associated with the process tool controller 50 for statistical analysis and subsequent process learning. The stored temperature data file could be exported from the tool 50 via an “e-Diagnostics” path 70 to a supplier factory location for off-line tool/process engineering diagnostic analysis and/or real-time tool calibration. As known, an e-Diagnostics solution provider enables continuous remote access to enterprise information and operations for process optimization. Particularly, e-Diagnostics is a method of tool control and problem diagnostics analysis performed externally from a remote facility. Particularly, e-Diagnostics is a terminology used to describe the process of collecting data processing that data and providing feedback. As known in the industry, there are many different programs available for e-diagnostics.

Alternately, the wafer sensor data may be sent to a software simulation program that determines, from the real-time wafer sensor data, the process recipe operating ranges to enable recipe matrix setup, enhance recipe effectiveness and reduce recipe setup times. Moreover, the placement of sensor chips on the monitor wafer provides real-time feedback on test sites, end point, arcing, and plasma confinement. Furthermore, placement of the sensor chips on product wafers provides real time tracking status of the job. Such data may be used for analyzing bottlenecks in the production line and true throughput numbers.

FIG. 2 illustrates a detailed schematic diagram of a single detailed sensor IC chip 15 embedded on the monitor wafer 10 according to a preferred embodiment of the invention. As shown in FIG. 2, the embedded sensor IC chip 15 comprises a sensor device 80, including, but not limited to: a temperature sensor, pressure sensor, conductivity sensor, gas flow, humidity, air velocity, incident energy/radiation sensor, eddy current sensor, magnetism, noise, shock, strain, stress, vibration, etc. These sensor devices may be capacitive, resistive, thin-film, and may include a MEMS (microelectromechanical systems) based or NEMS (nanoelectromechanical systems) based sensor devices. Other sensor types not explicitly recited herein may be used in conjunction with the monitor wafer sensor platform for monitoring real-time semiconductor fabrication process conditions in accordance with the present invention. Coupled to the sensor device 80 is an A/D converter device 83, that converts analog signals output form the sensor 80 into a digital signal that may be stored in a local on-board chip memory 85 (e.g., a register, ROM or RAM memory). Additionally, included in the wafer, are an antenna circuit 90 adapted for receiving RF signals which may include radio frequencies, such as amplitude or frequency modulated that are generated by the chamber processes, an AC/DC power converter unit 93, and an RF transmitter circuit 95. In operation, chamber RF power signals 22 are radiated from the process tool during operation and are received by antenna 90. These signals are essentially converted to an activation voltage by the AC/DC power converter unit 93 so as to provide power for the devices of the onboard chip 15. Once the chip is energized, the sensor 80 is activated and provides an analog signal. This analog signal data is passed to the Analog to Digital Converter (ADC) 83 and is converted to a stream of digital data and stored in the onboard chip memory 85. Using the same antenna 90 path as the incoming RF signal, an RF signal is generated by the transmitter circuit 95 and stored sensor data is transmitted to the external receiver 30 located outside the process tool. The primary function of the chip 15 is to provide sensed data taken within the chamber at the monitor wafer and communicate this data externally without wires or probes. The onboard memory circuit 85 has been designed to include a fixed and unique chip identification number, i.e., chip ID 86 and will be addressed by the receiver with each data transmission. The chip is activated only when RF power is present and sensed by the antenna circuit 90. The chip ID data 86 that identifies the particular sensor type and location on the wafer may be stored as a digital signal, along with the sensed process condition parameter data. In response to receipt of the RF signal including the sensed condition information and chip ID data, the tool controller 50 identifies the sensor type, and may then automatically perform all the necessary setup, configuration and tooling adjustments. These operational parameters can be manually modified by the user, or automatically based on predetermined recipes implemented in the tool controller.

It is understood that there is inherently a wide power range due to the high power sources available within the processing tool's chamber coupled with the ability for flexible antenna lengths designed within the chip and or wafer. Thus, each wafer may contain multiple chips (chip array) each having unique ID's and sensors with unique power requirements.

As many embedded sensor chips 15 are provided on the monitor wafer 10 that are capable of communicating externally to the tool controller 50 via the receiver/CPU 30 and tool interface 40, the monitoring performed by the present invention provides all the power needed to operate the sensor devices in the processing chamber, identifies sensors that are connected to the system, and configures appropriate operating parameters without operator intervention, and provides centralized simultaneous control, monitoring and recordation for the plurality of sensors and the data provided thereby on a storage medium (not shown).

Further beneficial aspects of the present invention thus include, but are not limited to: 1) the system allows ‘real-time’ tool/chamber temperature control and recipe setup; 2) the system provides Design of Experiment data based on specific on wafer chip position within the chamber and on the wafer chuck; 3) the system enables the superior profiling of chuck zone temperatures due to true-to-life wafer positioning. That is, the ability to map wafer chuck temperatures at strategic points on the wafer during an actual process step is a tremendous advantage for the process engineer to calibrate a tool recipe process as well as with real-time feedback to maintain chamber/chuck temperatures during continued wafer to wafer processing; 4) the system provides process parameter consistency/calibration using single monitor wafer; 5) the system provides improved tool utilization—less time required to setup and profile and apply calibrations; 6) the system provides improved process yields due to precise tool and chamber matching ability; 7) the system provides and improves the accuracy of temperature measurement when compared to thermal couple-no thermal losses due to thermal mass of TC wires; and, 8) the system provides improved precision of the measurement—dependence of visual perception of color of dots is replaced by digital information.

While there has been shown and described what is considered to be preferred embodiments of the invention, it will, of course, be understood that various modifications and changes in form or detail could readily be made without departing from the spirit of the invention. It is therefore intended that the invention be not limited to the exact forms described and illustrated, but should be constructed to cover all modifications that may fall within the scope of the appended claims.

Having thus described our invention, what we claim as new, and desire to secure by Letters Patent is:

1. An apparatus for real-time monitoring of process conditions of a semiconductor wafer processing operation comprising:
a wafer processing tool adapted to receive and process a semiconductor wafer therein, said semiconductor wafer including one or more sensor devices embedded therein;
a means for generating wireless electromagnetic signals for receipt by said embedded one or more sensor devices, said embedded sensor device generating sensory data in response to said electromagnetic signals,
a transmitter means provided in said wafer for transmitting said sensory data;
a receiver means located externally from said wafer processing tool for receiving said transmitted sensory data; and,
a means for controlling processing conditions of the wafer process tool based upon the received sensory data.

2. The apparatus as claimed in claim 1, wherein means for generating said electromagnetic signals comprises a Radio Frequency (RF) transmitter, said electromagnetic signals comprising RF signals.

3. The apparatus as claimed in claim 2, further comprising:
an antenna device embedded in said wafer for receiving said RF signals; and,
a means for converting received RF signals into voltage signals for input to an embedded sensor device for activating said device.

4. The apparatus as claimed in claim 1, wherein said transmitter means provided in said wafer for transmitting said sensory data comprises an RF signal transmitter device for transmitting said sensory data via RF signals.

5. The apparatus as claimed in claim 1, further comprising:
a means for converting sensory data obtained from said embedded sensor device to digital signals; and,
means for storing said digital signals provided on said wafer prior to transmission.

6. The apparatus as claimed in claim 1, wherein each said one or more embedded sensor devices includes an associated unique identification code, said unique identification code stored in a memory storage device associated with said sensor, said sensory data being transmitted along with said unique identification code to thereby identify the sensor device at the receiver means.

7. The apparatus as claimed in claim 6, wherein said unique identification code associates said sensor device with a particular location on the wafer, said means for controlling processing conditions of the wafer process tool further identifying a wafer location where received sensor data originated.

8. The apparatus as claimed in claim 7, wherein said sensor device comprises a temperature sensor, said sensory data comprising wafer temperature at a particular location on said wafer.

9. The apparatus as claimed in claim 8, wherein said means for controlling processing conditions of the wafer process tool further comprises means for profiling wafer chuck zone temperatures due to wafer positioning.

10. The apparatus as claimed in claim 8, wherein said means for controlling processing conditions of the wafer process tool further comprises:
a means for processing said sensory data to calculate correction factors and new operating range setpoints for said wafer process tool;
a means for communicating said correction factors and new operating range setpoints to said wafer process tool; and,
a means for providing real-time adjusting of processing condition parameters in response to said correction factors and new operating range setpoints.

11. A system for controlling processing condition parameters of a wafer processing chamber comprising:
a means for generating RE signals for receipt by a monitoring wafer positioned within said chamber, said monitoring wafer having one or more embedded sensor circuits, each embedded sensor circuit comprising:
a sensor device adapted for generating environmental parameter sensory data;
an antenna device for receiving said RF signals;
a means for converting received RF signals into voltage signals for input to a sensor device for activating said sensor device;
a means for converting sensory data obtained from said embedded sensor device to digital signals;
a means for storing said digital signals representing said sensory data; and,
an RF transmitter means adapted for wirelessly transmitting said sensory data;
a receiver means located externally from said wafer processing tool for receiving said transmitted sensory data; and,
a processing means for calculating operating condition correction factors and operating range setpoints based upon said received sensory data; and,
means for providing real-time adjusting of processing condition parameters in response to said correction factors and new operating range setpoints.

12. The system as claimed in claim 11, wherein each said each embedded sensor circuit includes an associated unique identification code, said unique identification code stored in said storing means, said unique identification code being transmitted along with said sensory data to thereby identify the sensor device at the receiver means.

13. The system as claimed in claim 12, wherein said unique identification code associates said sensor device with a particular location on the wafer, said processing means further identifying a monitor wafer location where received sensor data originated.

14. The system as claimed in claim 12, wherein said processing condition parameters include one ore more of: temperature, RF power, gas flows, pressures, DC bias voltages, either singly or in combination.

15. A system for calibrating a semiconductor wafer process chamber utilizing the monitoring wafer as claimed in claim 12.
